(19) United States
(12) Patent Application Publication
(10) Pub. No.: US 2026/0136893 A1
(43) Pub. Date: May 14, 2026

(54) DEFECT REPAIRING APPARATUSES AND METHODS OF REPAIRING DEFECTS

(71) Applicant: Taiwan Semiconductor Manufacturing Company, Ltd., Hsinchu (TW)

(72) Inventors: Xiaomeng CHEN, Hsinchu (TW); Ding-Shiun TU, Hsinchu (TW); Kuang-Shing CHEN, Hsinchu (TW); Wei-Jen LO, Hsinchu (TW)

(73) Assignee: Taiwan Semiconductor Manufacturing Company, Ltd., Hsinchu (TW)

(21) Appl. No.: 19/043,746

(22) Filed: Feb. 3, 2025

Related U.S. Application Data
(60) Provisional application No. 63/720,530, filed on Nov. 14, 2024.

(51) Int. Cl. H01L 21/66; H01L 21/67

(52) U.S. Cl. CPC H10P 74/238; H10P 72/0428; H10P 74/203

(57) ABSTRACT

A target wafer repairing apparatus is provided. The target wafer repairing apparatus includes a chamber configured to load a target wafer, and a particle beam source configured to emit one or more beamlets to irradiate a repair region of the target wafer. The repairing apparatus further includes at least one gas inlet configured to inject a precursor gas to the repair region of the target wafer to repair defects in the repair region of the target wafer.

### RELATED APPLICATION

This application claims priority to U.S. Provisional Application No. 63/720,530 filed Nov. 14, 2024, the entire disclosure of which is incorporated herein by reference.

### BACKGROUND

Defect repairing is an important process to improve the yield of advanced semiconductor manufacturing processes. However, defect repairing mostly relies on chip-level repairing tools, which require the wafer to be broken into individual chips even when most of the remaining chips on the wafer are defect-free. The entire wafer will be wasted as a result. Thus, improved repairing apparatuses and methods for repairing defects on the wafer are desirable.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a schematic view of a repairing apparatus in accordance with some embodiments of the present disclosure.

FIG. 2A illustrates a schematic view of a repairing apparatus in accordance with some embodiments of the present disclosure.

FIG. 2B illustrates a diagram of a grouping pattern example of arranging the plurality of apertures in accordance with some embodiments of the present disclosure.

FIG. 3 illustrates a schematic view of a repairing system in accordance with some embodiments of the present disclosure.

FIG. 4 illustrates a block diagram for repairing a target wafer in accordance with some embodiments of the present disclosure.

FIG. 5 illustrates a flow diagram of a method for operating a repairing apparatus in accordance with some embodiments of the present disclosure.

FIGS. 6A and 6B illustrate a computer system for implementing various methods in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. In addition, the term “being made of” may mean either “comprising” or “consisting of.” In the present disclosure, a phrase “one of A, B and C” means “A, B and/or C” (A, B, C, A and B, A and C, B and C, or A, B and C), and does not mean one element from A, one element from B and one element from C, unless otherwise described.

Defect-repairing processes mostly rely on chip-level defect-repairing tools. However, chip-level defect-repairing tools are limited in their capacity to scale to the wafer level due to constraints such as vacuum-level requirements, contamination from gas residues, and prolonged processing times. Embodiments of this disclosure provide improved apparatuses and methods for repairing defects in a target wafer, thereby reducing the contamination risks and improving the repairing efficiency. In some embodiments, the improved apparatuses and methods include using a multi-head primary gun or a micro-electro-mechanical system (MEMS) to provide a plurality of beamlets to simultaneously repair multiple defects, thereby improving the repairing efficiency. In some embodiments, different repair functions are performed in different chambers, thereby reducing the cross-contamination from gas residues. Consequently, the defects of the target wafer can be efficiently reduced, and the yield of the wafer product can be improved.

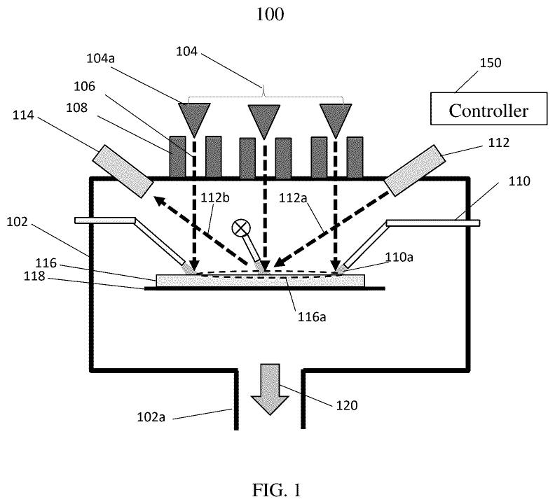

FIG. 1 illustrates a schematic view of a repairing apparatus 100 in accordance with some embodiments of the present disclosure. In some embodiments, the repairing apparatus 100 is a wafer repairing apparatus. In some embodiments, the repairing apparatus 100 includes a chamber 102 and a particle beam source 104 to provide a particle beam for the repairing apparatus 100.

In some embodiments, the chamber 102 is a vacuum chamber. In some embodiments, the chamber 102 includes a chamber outlet 102a. The chamber outlet 102a is coupled with and/or connected to a vacuum pump system 120 to produce and maintain a vacuum in the chamber 102.

In some embodiments, the particle beam source 104 is an ion beam source. In some embodiments, the ion beam source is configured to emit an ion beam. In some embodiments, the ion beam source includes an ion generator or an ion gun. For example, positively or negatively charged ions can be generated from a gas, such as hydrogen, helium, nitrogen, oxygen, neon, argon, krypton, xenon, a carbon containing gas.

Alternatively, in some embodiments, the particle beam source 104 is an electron beam source. In some embodiments, the electron beam source is configured to emit an electron beam. In some embodiments, the electron beam source includes an electron generator or an electron gun. For example, electrons can be generated from a conducting material by heating the conducting material to a high temperature, whereby the electrons have sufficient energy to overcome a work function barrier and escape from the conducting material (thermionic sources). For further example, electrons can also be generated by applying an electric field sufficiently strong so that electrons tunnel through the work function barrier of a conducting material (field emission sources).

In some embodiments, the particle beam source 104 includes at least one gun head 104a. In some embodiments, the at least one gun head 104a is configured to convert the particle beam to at least one beamlet 106. In some embodiments, the at least one beamlet 106 includes at least two beamlets 106 that are parallel to each other. In some examples, a beamlet of the at least one beamlet 106 includes more than one sub-beamlet.

In some embodiments, each of the at least one gun head 104a is configured to be moveable, such that each of the at least one beamlet 106 can irradiate a specific target spot on a surface of a target wafer 116.

In some embodiments, the repairing apparatus 100 further includes at least one electrode pair 108 configured to control the at least one beamlet 106. In some embodiments, each of the at least one electrode pair 108 are positioned around a corresponding beamlet of the at least one beamlet 106. In some embodiments, each of the at least one electrode pair 108 is configured to control the direction, the beam spot size, and the shape of a corresponding beamlet of the at least one beamlet 106. In some embodiments, the at least one electrode pair 108 includes at least two electrode pair 108. In some embodiments, each of the at least two electrode pair 108 are configured to control the corresponding particle beamlet, such that the at least two beamlets 106 are parallel to each other.

In some embodiments, each of the at least one electrode pair 108 is configured to project the corresponding particle beamlet through the at least one electrode pair 108 to a desired target spot on the target wafer 116. In some embodiments, each of the at least one electrode pair 108 is configured to precisely control the beam spot size of the corresponding beamlet of the at least one beamlet 106, such that the corresponding beamlet is uniformly distributed on the desired target spot. In some embodiments, the shape of the corresponding beamlet of the at least one beamlet 106 is circular, elliptical, or any other suitable shape.

Although three gun heads 104a and three electrode pairs 108 are shown in the repairing apparatus 100, any suitable number of gun heads 104a and electrode pairs can be included in the repairing apparatus 100. In some embodiments, there are fewer than three gun heads 104a and three electrode pairs 108. In some embodiments, there are more than three gun heads 104a and three electrode pairs 108. In some embodiments, the repairing apparatus 100 includes one gun head 104a and one electrode pair 108.

In some embodiments, the repairing apparatus 100 further includes at least one gas inlet 110 configured to introduce and/or inject a precursor gas to the chamber 102. In some embodiments, each of the at least one gas inlet 110 is configured to feed a precursor gas flow 110a to a corresponding target spot. In some embodiments, the at least one gas inlet 110 is coupled with and/or connected to a precursor gas reservoir to provide the precursor gas.

In some embodiments, the at least one gas inlet 110 is coupled with and/or connected to multiple precursor gas reservoirs to provide different precursor gases.

In some embodiments, the repairing apparatus 100 further includes a wafer stage 118 configured to hold the target wafer 116. In some embodiments, the wafer stage 118 secures the target wafer 116 using a vacuum, e-chucking, or other suitable methods, and provides an accurate positioning and movement of the target wafer 116 relative to the at least one beamlet 106. In some embodiments, the wafer stage 118 includes motors, roller guides, and/or tables.

In some embodiments, the target wafer 116 includes a repair region 116a. In some embodiments, the repair region 116a of the target wafer 116 includes defects on the target wafer 116. In some embodiments, defects in the repair region 116a are detected and classified before the target wafer 116 is transferred to the repairing apparatus 100.

In some embodiments, the at least one beamlet 106 is arranged perpendicular to a top surface of the target wafer 116. In some embodiments, a pair of electrodes 108 functions as an electrical-optical lens that focuses the at least one beamlet 106 onto the top surface of the target wafer 116. The electrical-optical lenses use an electrical field to control the at least one beamlet 106. In some embodiments, each of the at least one beamlet 106 is focused on the top surface of the target wafer 116, such that each of the at least one beamlet 106 has a high enough energy to dissociate the precursor gas at the top surface of the target wafer 116.

In some embodiments, the precursor gas includes a reactant gas and a carrier gas. The precursor gas is directed at at least one target spot, such that molecules of the precursor gas can be dissociated by the radiation of the at least one beamlet 106 directed at the corresponding at least one target spot.

In some embodiments, the precursor gas includes metalorganic compounds and/or metal-halogen complexes for metal and/or metal-oxide deposition. In some embodiments, the precursor gas includes silanes, alkoxysilanes, and/or alkyl-aryl silanes for SiO₂ deposition. For example, the dissociated molecules of the precursor gas can be deposited on the repair region 116a to repair the defects on the target wafer 116.

In some embodiments, the precursor gas includes compounds having elements of hydrogen, halogens, oxygen, nitrogen, and/or noble gases for etching. For example, the dissociated molecules of the precursor gas can etch the repair region 116a to repair the defects on the target wafer 116.

In some embodiments, the repairing apparatus 100 further includes a detecting beam generator 112 and a detector 114. In some embodiments, the detecting beam generator 112 is a particle beam generator configured to emit a detecting beam 112a to scan the top surface of the target wafer 116. In some embodiments, the particle beam is an electron beam. In some embodiments, the detecting beam generator 112 is a light beam generator configured to emit a light beam. In some embodiments, the light beam generator 112 is a laser beam generator. In some embodiments, the light beam generator 112 generates an infrared, a visible, or an ultraviolet light beam. In some embodiments, the detector 114 detects a reflected beam 112b of the detecting beam 112a from the top surface of the target wafer 116. In some embodiments, the detector 114 is an electron detector that detects reflected electrons or a light sensor that detects reflected light. In some embodiments, the detector 114 is further configured to image the surface of the target wafer 116 based on the reflected beam 112b. In some embodiments, the top surface of the target wafer 116 is imaged.

In some embodiments, the detecting beam 112a is directed to the top surface of the target wafer 116 in a tilted direction relative to a normal direction to the top surface of the target wafer 116. In some embodiments, a tilting angle between the detecting beam 112a and the normal direction to the top surface of the target wafer 116 is in a range from about 15° to about 75°. In some embodiments, the tilting angle between the detecting beam 112a and the normal direction to the top surface of the target wafer 116 is in a range from about 30° to about 60°. In some embodiments, each of the at least one beamlet 106 is directed to the top surface of the wafer 116 in a normal direction relative to the top surface of the target wafer 116.

In some embodiments, the repairing apparatus 100 further includes a controller 150 electrically or wirelessly connected to and/or coupled with the particle beam source 104, the at least one electrode pair 108, the at least one gas inlet 110, the detecting beam generator 112, the detector 114, and the wafer stage 118. The controller 150 is configured to receive and process the data generated from the particle beam source 104, the at least one electrode pair 108, the at least one gas inlet 110, the detecting beam generator 112, the detector 114, and the wafer stage 118. In some embodiments, the controller 150 is a microcontroller configured to receive and process the generated data and adjust setting parameters of the particle beam source 104, the at least one electrode pair 108, the at least one gas inlet 110, the detecting beam generator 112, the detector 114, and the wafer stage 118 based on the generated data.

In some examples, the controller 150 is communicatively coupled with and/or connected to the particle beam source 104 and the at least one electrode pair 108 to control the power, timing, and/or trajectories of the at least one beamlet 106.

In some examples, the controller 150 is communicatively coupled with and/or connected to the at least one gas inlet 110 to control the flow rate, timing, and/or trajectories of the at least one precursor gas flow 110a. In some embodiments, the controller 150 is configured to synchronize the emission of the at least one beamlet and the injection of the precursor gas, such that multiple defects on the target wafer 116 can be simultaneously repaired, thereby improving the repairing efficiency.

In some examples, the controller 150 is communicatively coupled with and/or connected to the wafer stage 118 to provide accurate positioning and movement of the target wafer 116 relative to the at least one beamlet 106.

In some examples, the controller 150 includes software and hardware for image storage, image comparison, and image evaluation. In one example, the controller 150 includes a media, such as a flash memory device or a hard disk, to save the images of the surface of the target wafer 116 from the detector 114. In another embodiment, the controller 150 includes an algorithm that processes a plurality of images associated with the surface of the target wafer 116, to determine whether the defects of the target wafer 116 are repaired based on the image of the surface of the target wafer 116.

It is understood that the controller 150 may be concentrated at a single location or distributed. In one embodiment, the controller 150 is embedded in the repairing apparatus 100. In another embodiment, the controller 150 is remotely connected to the repairing apparatus 100 through the internet, intranet, or other data communication mechanisms. In yet another embodiment, the controller 150 is a portion of a semiconductor device manufacturing system and is coupled to the repairing apparatus 100 through a suitable data communication mechanism.

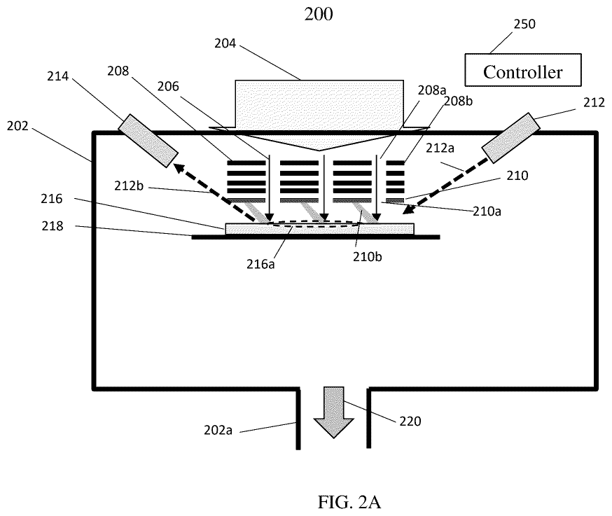

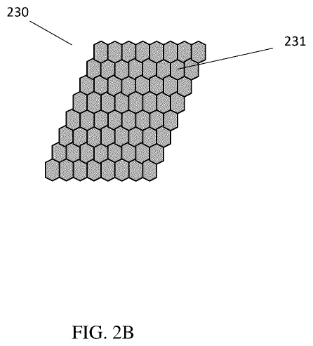

FIG. 2A illustrates a schematic view of a repairing apparatus 200 in accordance with some embodiments of the present disclosure. In some embodiments, the repairing apparatus 200 is a wafer repairing apparatus. In some embodiments, the repairing apparatus 200 includes a chamber 202 and a particle beam source 204 to provide a particle beam for the repairing apparatus 200.

In some embodiments, the chamber 202 is a vacuum chamber. In some embodiments, the chamber 202 includes a chamber outlet 202a. The chamber outlet 202a is coupled with and/or connected to a vacuum pump system 220 to produce and maintain a vacuum in the chamber 202.

In some embodiments, the particle beam source 204 is an ion beam source. In some embodiments, the ion beam source is configured to emit an ion beam. In some embodiments, the ion beam source includes an ion generator or an ion gun. For example, positively or negatively charged ions can be generated from a gas, such as hydrogen, helium, nitrogen, oxygen, neon, argon, krypton, xenon, and a carbon-containing gas.

Alternatively, in some embodiments, the particle beam source 204 is an electron beam source. In some embodiments, the electron beam source is configured to emit an electron beam. In some embodiments, the electron beam source includes an electron generator or an electron gun. For example, electrons can be generated from a conducting material by heating the conducting material to a high temperature, whereby the electrons have sufficient energy to overcome a work function barrier and escape from the conducting material (thermionic sources). Electrons can also be generated by applying an electric field sufficiently strong so that electrons tunnel through the work function barrier of a conducting material (field emission sources).

In some embodiments, the particle beam source 204 is configured to provide a particle beam.

In some embodiments, the repairing apparatus 200 further includes a first micro-electro-mechanical system (MEMS) device 208 configured as a beam-splitting device and/or a beam-stopping device in association with the particle beam source 204.

In some embodiments, the first MEMS device 208 includes a plurality of apertures 208a arranged in an array, such that the particle beam from the particle beam source 204 is split into a plurality of beamlets 206. In some embodiments, the first MEMS device 208 includes one or more layers 208b configured to enhance the shape of the plurality of beamlets 206.

FIG. 2B illustrates a diagram of a grouping pattern example of arranging the plurality of apertures in accordance with some embodiments.

In some embodiments, as shown in FIG. 2B, the plurality of apertures 208a are arranged at positions corresponding to hexagons 231 of a group pattern 230.

In some embodiments, the first MEMS device 208 further includes electromagnetic deflectors configured to control the plurality of beamlets 206. In some embodiments, the electromagnetic deflectors provide a time-varying electric field. In some embodiments, the first MEMS device 208 is configured to control a plurality of beamlets 206, such that the plurality of beamlets 206 are parallel to each other. In some embodiments, the first MEMS device 208 is configured to project each of the plurality of beamlets 206 passing through first MEMS device 208 to a target spot on the target wafer 216. In some embodiments, the first MEMS device 208 is configured to block any of the plurality of beamlets 206 from passing through the first MEMS device 208.

In some embodiments, the repairing apparatus 200 further includes a second micro-electro-mechanical system (MEMS) device 210 configured as a precursor gas delivery device. In some embodiments, the second MEMS device 210 includes a plurality of openings 210a to allow the plurality of beamlets 206 to pass through the second MEMS device 210. In some embodiments, the second MEMS device 210 is a microchannel MEMS device configured to control a plurality of gas flows 210b.

In some embodiments, the second MEMS device 210 includes a plurality of outlets arranged in an array, such that the precursor gas is fed to a corresponding target spot of each of the plurality of beamlets 206 through the plurality of outlets of the second MEMS device 210. In some embodiments, the second MEMS device 210 further includes internal microchannels connecting the plurality of outlets to a precursor gas reservoir to provide the precursor gas. In some embodiments, the second MEMS device 210 is configured to provide a gas flow 210b to each target spot corresponding to the plurality of beamlets 206 in a repair region 216a of the target wafer 216.

In some embodiments, the second MEMS device 210 further includes a regulator configured to control a gas flow rate of each of the plurality of gas flows 210b.

In some embodiments, the repairing apparatus 200 further includes a wafer stage 218 configured to hold the target wafer 216. In some embodiments, the wafer stage 218 secures the target wafer 216 using a vacuum, e-chucking, or other suitable methods, and provides accurate positioning and movement of the target wafer 216 relative to the plurality of beamlets 206. In some embodiments, the wafer stage 218 includes motors, roller guides, and/or tables.

In some embodiments, the target wafer 216 includes the repair region 216a. In some embodiments, the repair region 216a of the target wafer 216 includes defects on the target wafer 216. In some embodiments, the defects in the repair region 216a are detected and classified before the target wafer 216 is transferred to the repairing apparatus 200.

In some embodiments, the plurality of beamlets 206 are directed perpendicular to a top surface of the target wafer 216. In some embodiments, the first MEMS device 208 functions as a lens and focuses the plurality of beamlets 206. In some embodiments, each of the plurality of beamlets 206 is focused on the top surface of the target wafer 216, such that each of the plurality of beamlets 206 has a high enough energy to dissociate the precursor gas at the top surface of the target wafer 216.

In some embodiments, the precursor gas includes a reactant gas and a carrier gas. The precursor gas is directed at at least one target spot, such that molecules of the precursor gas can be dissociated by the radiation of the plurality of beamlets 206 directed at the corresponding target spots.

In some embodiments, the precursor gas includes metal-organic compounds and/or metal-halogen complexes for metal and/or metal-oxide deposition. In some embodiments, the precursor gas includes silanes, alkoxysilanes, and/or alkyl-aryl silanes for SiO₂ deposition. For example, the dissociated molecules of the precursor gas can be deposited on the repair region 216a to repair the defects on the target wafer 216.

In some embodiments, the precursor gas includes compounds having elements of hydrogen, halogens, oxygen, nitrogen, and/or noble gases for etching. For example, the dissociated molecules of the precursor gas can etch the repair region 216a to repair the defects on the target wafer 216.

In some embodiments, the repairing apparatus 200 further includes a detecting beam generator 212 and a detector 214. In some embodiments, the detecting beam generator 212 is an electron beam generator configured to emit a detecting beam 212a to scan the surface of the target wafer 216. In some embodiments, the detecting beam generator 212 is a light beam generator configured to emit a light beam to scan the surface of the target wafer 216. In some embodiments, the detector 214 detects a reflected beam 212b of the detecting beam 212a from the surface of the target wafer 216. In some embodiments, the detector 214 is an electron detector that detects reflected electrons or a light sensor that detects reflected light. In some embodiments, the light beam generator 212 is a laser beam generator. In some embodiments, the light beam generator emits infrared, visible, or ultraviolet light beams. In some embodiments, the detector 214 is further configured to image the surface of the target wafer 216 based on the reflected beam 212b.

In some embodiments, the detecting beam 212a is directed to the top surface of the target wafer 216 in a tilted direction relative to a direction normal to the top surface of the target wafer 216. In some embodiments, a tilting angle between the detecting beam 212a and the normal direction to the top surface of the target wafer 216 is in a range from about 15° to about 75°. In some embodiments, the tilting angle between the detecting beam 212a and the normal direction to the top surface of the target wafer 216 is in a range from about 30° to about 60°. In some embodiments, each of the plurality of beamlets 206 is directed to the top surface of the target wafer 216 in a normal direction to the top surface of the target wafer 216.

In some embodiments, the repairing apparatus 200 further includes a controller 250 electrically or wirelessly connected to and/or coupled with the particle beam source 204, the first MEMS device 208, the second MEMS device 210, the detecting beam generator 212, the detector 214, and the wafer stage 218. The controller 250 is configured to receive and process the data generated from the particle beam source 204, the first MEMS device 208, the second MEMS device 210, the detecting beam generator 212, the detector 214, and the wafer stage 218. In some embodiments, the controller 250 is a microcontroller configured to receive and process the generated data and adjust setting parameters of the particle beam source 204, the first MEMS device 208, the second MEMS device 210, the detecting beam generator 212, the detector 214, and the wafer stage 218 based on the generated data.

In some examples, the controller 250 is communicatively coupled with and/or connected to the particle beam source 204 and the first MEMS device 208 to control the power, timing, and/or trajectories of the plurality of beamlets 206.

In some examples, the controller 250 is communicatively coupled with and/or connected to the second MEMS device 210 to control the flow rate, timing, and/or trajectories of the plurality of gas flows 210b. In some embodiments, the controller 150 is configured to synchronize the plurality of beamlets 206 and the injection of the precursor gas, such that multiple defects on the target wafer 216 can be simultaneously repaired, thereby improving the repairing efficiency.

In some examples, the controller 250 is communicatively coupled with and/or connected to the wafer stage 218 to provide accurate positioning and movement of the target wafer 216 relative to the plurality of beamlets 206.

In some examples, the controller 250 includes software and hardware for image storage, image comparison, and image evaluation. In an example, the controller 250 includes a media, such as a flash memory device or a hard disk, to save the images of the surface of the target wafer 216 from the detector 214. In another embodiment, the controller 250 includes an algorithm that processes a plurality of images associated with the surface of the target wafer 216, to determine whether the defects of the target wafer 216 are repaired.

It is understood that the controller 250 may be concentrated at a single location or distributed. In one embodiment, the controller 250 is embedded in the repairing apparatus 200. In another embodiment, the controller 250 is remotely connected to the repairing apparatus 200 through the internet, intranet, or other data communication mechanisms. In yet another embodiment, the controller 250 is a portion of a semiconductor device manufacturing system and is coupled to the repairing apparatus 200 through a suitable data communication mechanism.

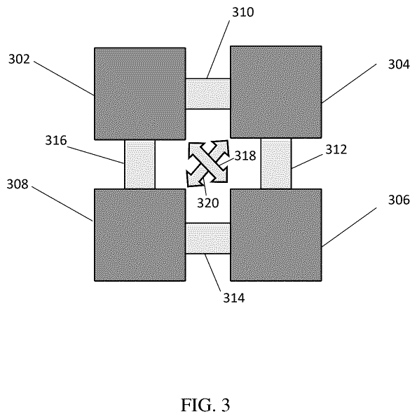

FIG. 3 illustrates a schematic view of a repairing system 300 in accordance with some embodiments of the present disclosure. In some embodiments, the repairing system 300 includes a first repairing apparatus 302, a second repairing apparatus 304, and a first transfer mechanism 310 coupling and/or connecting the first repairing apparatus 302 and the second repairing apparatus 304.

In some embodiments, the repairing system 300 further includes a third repairing apparatus 306 and a second transfer mechanism 312 coupling and/or connecting the second repairing apparatus 304 and the third repairing apparatus 306.

In some embodiments, the repairing system 300 further includes a fourth repairing apparatus 308 and a third transfer mechanism 314 coupling and/or connecting the third repairing apparatus 306 and the fourth repairing apparatus 308.

In some embodiments, the repairing system 300 further includes a fourth transfer mechanism 316 coupling and/or connecting the fourth repairing apparatus 308 and the first repairing apparatus 302.

In some embodiments, the repairing system 300 further includes a fifth transfer mechanism 318 coupling and/or connecting the first repairing apparatus 302 and the third repairing apparatus 306. In some embodiments, the repairing system 300 further includes a sixth transfer mechanism 320 coupling and/or connecting the second repairing apparatus 304 and the fourth repairing apparatus 308.

Although four repairing apparatuses and six transfer mechanisms are shown in the repairing system 300, any suitable number of repairing apparatuses and any number of transfer mechanisms coupling and/or connecting repairing apparatuses can be included in the repairing system 300. In some embodiments, there are fewer than four repairing apparatuses or more than four repairing apparatuses. In some embodiments, there are fewer than six transfer mechanisms or more than six transfer mechanisms.

In some embodiments, each of the first repairing apparatus 302, the second repairing apparatus 304, the third repairing apparatus 306, and the fourth repairing apparatus 308 used herein corresponds to the repairing apparatus 100 of FIG. 1 or the repairing apparatus 200 of FIG. 2A.

In some embodiments, at least one of the first repairing apparatus 302, the second repairing apparatus 304, the third repairing apparatus 306, and the fourth repairing apparatus 308 is a laser cutting apparatus or a laser annealing apparatus configured to remove defects having a size greater than 10 nm from the target wafer. In some embodiments, at least one of the first repairing apparatus 302, the second repairing apparatus 304, the third repairing apparatus 306, and the fourth repairing apparatus 308 is a scanning electron microscopy (SEM) apparatus configured to inspect and analyze the target wafer after the target wafer is repaired by the repairing apparatuses. In some embodiments, at least one of the first repairing apparatus 302, the second repairing apparatus 304, the third repairing apparatus 306, and the fourth repairing apparatus 308 is a nanoprobe apparatus configured to measure the properties of the chips on the target wafer.

In some embodiments, each of the first repairing apparatus 302, the second repairing apparatus 304, the third repairing apparatus 306, and the fourth repairing apparatus 308 is configured to perform a different defect-repairing function.

In some embodiments, the first repairing apparatus 302 is configured to repair defects of a first type. In some embodiments, the first repairing apparatus 302 is configured to repair defects of a second type. A size of the defects of the first type is greater than a size of the defects of the second type in some embodiments.

Each of the first transfer mechanism 310, the second transfer mechanism 312, the third transfer mechanism 314, the fourth transfer mechanism 316, the fifth transfer mechanism 318, and the sixth transfer mechanism 320 is configured to transfer the target wafer between the repairing apparatuses. In some embodiments, robotic arms and a vacuum or electrostatic chucking are used to physically transfer the target wafer between the repairing apparatuses. In some embodiments, a vacuum or reduced pressure atmosphere is maintained while the target wafer is being processed in each apparatus and while the target wafer is being transferred between repairing apparatuses.

Cross-contamination of precursor gas residues within each wafer-level chamber can be minimized by performing separate repairing steps in isolated chambers of multiple repairing apparatuses. Furthermore, the switching between different precursor gas sources is not needed, therefore operational efficiency can be further improved while effectively preventing cross-contamination of the precursor gas residues.

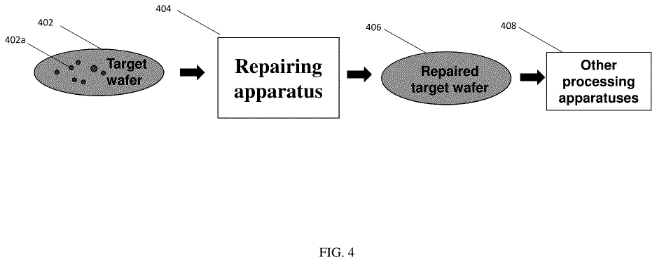

FIG. 4 illustrates a block diagram 400 for repairing a target wafer in accordance with some embodiments of the present disclosure.

In some embodiments, a target wafer 402 is provided and transferred to a repairing apparatus 404. The target wafer 402 includes defects 402a on a surface of the target wafer 402. In some embodiments, the defects 402a have different sizes. In some embodiments, the repairing apparatus 404 is configured to repair the defects 402a on the surface of the target wafer 402. In some embodiments, the repaired target wafer 406 is removed from the repairing apparatus 404. In some embodiments, the repaired target wafer 406 is further transferred to other processing apparatuses 408 to perform other operations on the repaired target wafer 406.

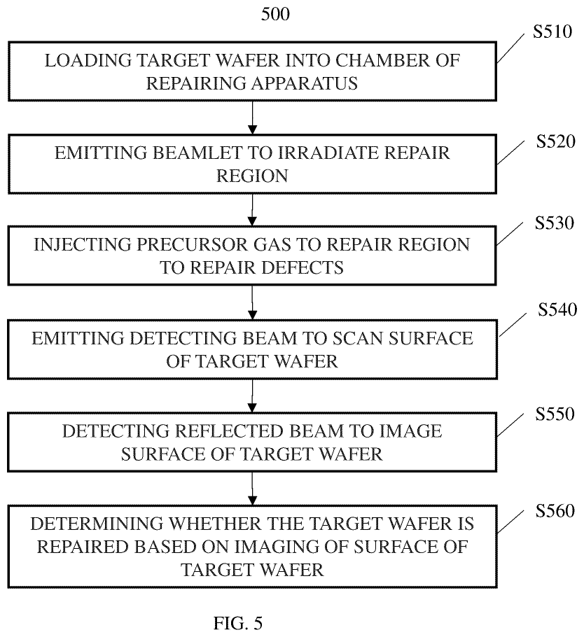

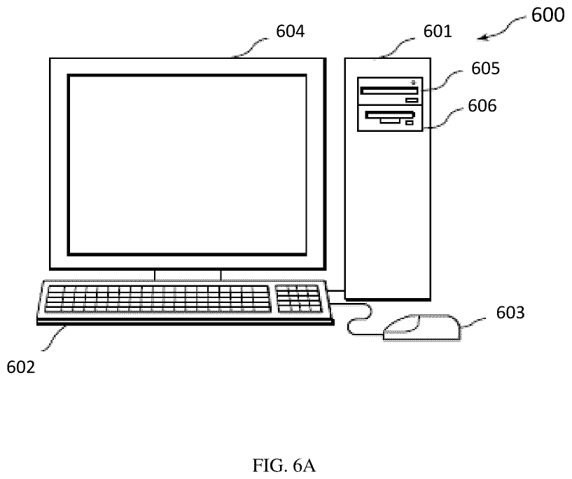

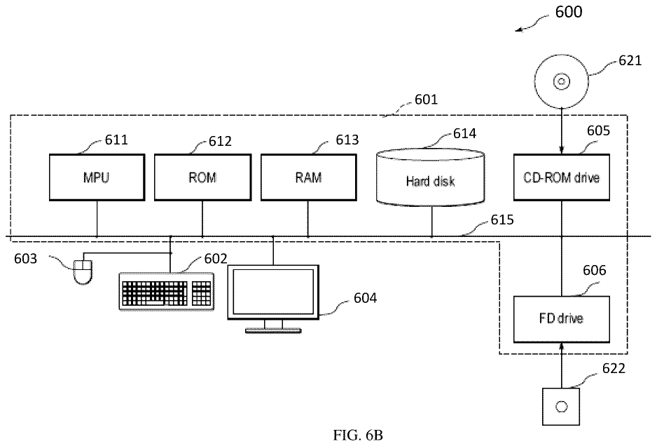

FIG. 5 illustrates a flow diagram of a method 500 for operating a repairing apparatus in accordance with some embodiments of the present disclosure. The method 500 or a portion of the method 500 is performed or controlled by a controller (e.g., 150 of FIG. 1 or 250 of FIG. 2A). In some embodiments, the method 500 or a portion of the method 500 is performed and/or is controlled by a computer system 600 described below with respect to FIGS. 6A and 6B. The method 500 is an example, and is not intended to limit the present disclosure and what is claimed. Additional operations can be provided before, during, and after the method 500, and some operations described can be replaced, eliminated, or the order of operations changed for additional embodiments of the method 500.

In some embodiments, the method 500 includes an operation S510 as shown in FIG. 5. In operation S510, a target wafer is loaded into a chamber of a repairing apparatus.

In some embodiments, as shown in FIG. 1, a target wafer 116 is loaded into the chamber 102 of the repairing apparatus 100. In some embodiments, as shown in FIG. 2A, a target wafer 216 is loaded into the chamber 202 of the repairing apparatus 200.

In some embodiments, the method further includes an operation S520 as shown in FIG. 5. In operation S520, at least one beamlet is emitted to irradiate a repair region of the target wafer.

In some embodiments, as shown in FIG. 1, at least one beamlet 106 is emitted by a particle beam source 104 of the repairing apparatus 100 to irradiate a repair region 116a of the target wafer 116. In some embodiments, as shown in FIG. 2A, a plurality of beamlets 206 are emitted to irradiate a repair region 216a of the target wafer 216.

In some embodiments, the method further includes an operation S530 as shown in FIG. 5. In operation S530, a precursor gas is injected to the repair region of the target wafer to repair defects in the repair region of the target wafer.

In some embodiments, as shown in FIG. 1, a precursor gas is injected by at least one gas inlet 110 of the repairing apparatus 100 to the repair region 116a of the target wafer 116 to repair defects in the repair region 116a of the target wafer 116. In some embodiments, as shown in FIG. 2A, a precursor gas is injected by a second MEMS device 210 of the repairing apparatus 200 to the repair region 216a of the target wafer 216 to repair defects in the repair region 216a of the target wafer 216.

In some embodiments, the operations S530 and S520 are performed simultaneously or are synchronized.

In some embodiments, the method further includes an operation S540 as shown in FIG. 5. In operation S540, a detecting beam is emitted by a detecting beam generator of the repairing apparatus to scan the surface of the target wafer.

In some embodiments, as shown in FIG. 1, a detecting beam 112a is emitted by a detecting beam generator 112 of the repairing apparatus 100 to scan the surface of the target wafer 116. In some embodiments, as shown in FIG. 2A, a detecting beam 212a is emitted by a detecting beam generator 212 of the repairing apparatus 200 to scan the surface of the target wafer 216.

In some embodiments, the method further includes an operation S550 as shown in FIG. 5. In operation S550, a reflected beam of the detecting beam is detected from the surface of the target wafer to image the surface of the target wafer based on the detected reflected beam.

In some embodiments, as shown in FIG. 1, a reflected beam 112b of the detecting beam 112a is detected from the surface of the target wafer 116 to image the surface of the target wafer 116 based on the detected reflected beam 112b. In some embodiments, as shown in FIG. 2A, a reflected beam 212b of the detecting beam 212a is detected from the surface of the target wafer 216 to image the surface of the target wafer 216 based on the detected reflected beam 212b.

In some embodiments, the operations S520, S530, S540, and S550 are performed simultaneously. In some embodiments, the operations S520, S530, S540, and S550 are synchronized.

In some embodiments, the method further includes an operation S560 as shown in FIG. 5. In operation S560, whether the target wafer is repaired is determined based on the imaging of the surface of the target wafer.

FIGS. 6A and 6B illustrate a computer system 600 for implementing various methods described herein in accordance with some embodiments of the present disclosure. In some embodiments, the computer system 600 is used for performing the functions of the controller 150 of FIG. 1 or the controller 250 of FIG. 2A, and/or operations of method 500 of FIG. 5.

FIG. 6A is a schematic view of a computer system that performs the functions of a repairing apparatus. All of or a part of the processes, methods, and/or operations of the foregoing embodiments can be realized using computer hardware and computer programs executed thereon. In FIG. 6A, a computer system 600 is provided with a computer 601 including an optical disk read only memory (e.g., CD-ROM or DVD-ROM) drive 605 and a magnetic disk drive 606, a keyboard 602, a mouse 603, and a monitor 604.

FIG. 6B is a diagram showing an internal configuration of the computer system 600. In FIG. 6B, the computer 601 is provided with, in addition to the optical disk drive 605 and the magnetic disk drive 606, one or more processors, such as a micro processing unit (MPU) 611, a read only memory (ROM) 612 in which a program such as a boot up program is stored, a random access memory (RAM) 613 that is connected to the MPU 611 and in which a command of an application program is temporarily stored and a temporary storage area is provided, a hard disk 614 in which an application program, a system program, and data are stored, and a bus 615 that connects the MPU 611, the ROM 612, and the like. Note that the computer 601 may include a network card for providing a connection to a local area network (LAN).

The program for causing the computer system 600 to execute the functions for the repairing apparatuses or the repairing system in the foregoing embodiments may be stored in an optical disk 621 or a magnetic disk 622, which are inserted into the optical disk drive 605 or the magnetic disk drive 606, and transmitted to the hard disk 614. Alternatively, the program may be transmitted via a network to the computer 601 and stored in the hard disk 614. At the time of execution, the program is loaded into the RAM 613. The program may be loaded from the optical disk 621 or the magnetic disk 622, or directly from a network. The program does not necessarily have to include, for example, an operating system (OS) or a third-party program to cause the computer 601 to execute the functions of the control system. The program may only include a command portion to call an appropriate function (module) in a controlled mode and obtain desired results.

The novel apparatuses and the methods according to the present disclosure provide improved apparatuses and methods for repairing a target wafer, thereby the contamination risks and improving the repairing efficiency. Embodiments of the disclosure provide apparatuses and methods using a multi-head gun or a micro-electro-mechanical system (MEMS) to provide a plurality of beamlets to simultaneously repair multiple defects, thereby improving the repairing efficiency. In some embodiments, the wafers do not need be broken into individual chips or fragments to repair, such that the number of wafers that have to be scrapped can be reduced during the repairing process. In some embodiments, apparatuses and methods using the multi-head gun or the micro-electro-mechanical system (MEMS) reduce the repairing time for a wafer by 1 to 2 orders of magnitude compared to apparatuses and methods using a single-head gun. In some embodiments, different repair functions are performed in different chambers, thereby reducing the cross-contamination from gas residues. Consequently, the defects of the target wafer can be efficiently reduced, and the yield of the wafer product can be improved.

According to some embodiments of the present disclosure, a target wafer repairing apparatus is provided. The target wafer repairing apparatus includes a chamber, and a particle beam source configured to emit one or more beamlets to irradiate a repair region of a target wafer disposed in the chamber. The target wafer repairing apparatus further includes one or more gas inlets configured to inject a precursor gas to the repair region of the target wafer to repair defects in the repair region of the target wafer. In an embodiment, the particle beam source includes at least one gun head configured to emit the one or more beamlets, and each of the at least one gun head is movable to irradiate a corresponding beamlet of the one or more beamlets to a target spot in the repair region of the target wafer. In an embodiment, the particle beam source is an ion beam source configured to provide an ion beam, wherein the at least one gun head is configured to convert the ion beam into the one or more beamlets. In an embodiment, the particle beam source is an electron beam source configured to provide an electron beam, wherein the at least one gun head is configured to convert the electron beam into the one or more beamlets. In an embodiment, the one or more beamlets are configured to be directed normal to a top surface of the target wafer. In an embodiment, each of the at least one gas inlet is arranged to inject the precursor gas at a corresponding target spot in the repair region of the target wafer. In an embodiment, the emitting of the one or more beamlets and the injecting of the precursor gas are synchronized. In an embodiment, the repairing apparatus further includes a detecting beam generator configured to emit a detecting beam to scan a top surface of the target wafer, and a detector configured to detect a reflected beam of the detecting beam from the surface of the target wafer and image the surface of the target wafer based on the detected reflected beam. In an embodiment, the detecting beam irradiates in a tilted direction in regard to the surface of the target wafer.

According to some embodiments of the present disclosure, a repairing apparatus is provided. The repairing apparatus includes a chamber, and a particle beam source configured to emit a particle beam. The repairing apparatus further includes a first micro-electro-mechanical system (MEMS) configured to split the particle beam into a plurality of beamlets to irradiate a repair region of a target wafer disposed in the chamber, and a second MEMS configured to inject a precursor gas to the repair region of the target wafer to repair defects in the repair region of the target wafer. In an embodiment, the first MEMS includes a plurality of apertures arranged in an array and configured to split the particle beam into a plurality of beamlets, and each of the plurality of apertures is configured to project a corresponding beamlet of the plurality of beamlets to a target spot in the repair region of the target wafer or block the corresponding beamlet of the plurality of beamlets from the target spot in the repair region of the target wafer. In an embodiment, the particle beam source is an ion beam source configured to provide an ion beam, wherein the first MEMS is configured to convert the ion beam into the plurality of beamlets. In an embodiment, the particle beam source is an electron beam source configured to provide an electron beam, wherein the first MEMS is configured to convert the electron beam into the plurality of beamlets. In an embodiment, the plurality of beamlets are normal to a top surface of the target wafer. In an embodiment, the second MEMS is a microchannel MEMS and is configured to provide a precursor gas flow to each target spot corresponding to the plurality of beamlets in the repair region of the target wafer. In an embodiment, the emitting of the plurality of beamlets and the injecting of the precursor gas are synchronized. In an embodiment, the repairing apparatus further includes a detecting beam generator configured to emit a detecting beam to scan a top surface of the target wafer, and a detector configured to detect a reflected beam of the detecting beam from the surface of the target wafer and image the surface of the target wafer based on the reflected beam of the detecting beam.

According to some embodiments of the present disclosure, a wafer repairing system includes a first wafer repairing apparatus. The first wafer repairing apparatus includes a first chamber, and a first particle beam source configured to emit a first particle beam into the first chamber. The first wafer repairing apparatus further includes a first micro-electro-mechanical system (MEMS) configured to split the first particle beam into a plurality of first beamlets to irradiate a first repair region of a target wafer disposed in the first chamber, and a second MEMS configured to inject a first precursor gas to the first repair region of the target wafer to repair first defects in the first repair region of the target wafer. In an embodiment, the wafer repairing system further includes at least one second target wafer repairing apparatus, and a transfer mechanism configured to transfer the target wafer between the first wafer repairing apparatus and the at least one second wafer repairing apparatus. Each of the at least one second wafer repairing apparatus includes a second chamber, and a second particle beam source configured to emit a second particle beam into the second chamber. Each of the at least one second wafer repairing apparatus further includes a third micro-electro-mechanical system (MEMS) configured to split the second particle beam into a plurality of second beamlets to irradiate a second repair region of the target wafer disposed in the second chamber, and a fourth MEMS configured to inject a second precursor gas to the second repair region of the target wafer to repair second defects in the second repair region of the target wafer. In an embodiment, the first MEMS includes a plurality of first apertures arranged in a first array and configured to split the first particle beam into a plurality of first beamlets, and each of the plurality of first apertures is configured to project a corresponding first beamlet of the plurality of first beamlets to a first target spot in the first repair region of the target wafer or block the corresponding first beamlet of the plurality of first beamlets from the first target spot in the first repair region of the target wafer. In an embodiment, the third MEMS includes a plurality of second apertures arranged in a second array and configured to split the second particle beam into a plurality of second beamlets, and each of the plurality of second apertures is configured to project a corresponding second beamlet of the plurality of second beamlets to a second target spot in the second repair region of the target wafer or block the corresponding second beamlet of the plurality of second beamlets from the second target spot in the second repair region of the target wafer. In an embodiment, the first particle beam source is a first ion beam source configured to provide a first ion beam, where the first MEMS is configured to convert the first ion beam into the plurality of first beamlets, and the second particle beam source is a second ion beam source configured to provide a second ion beam, where the third MEMS is configured to convert the second ion beam into the plurality of second beamlets. In an embodiment, the first particle beam source is a first electron beam source configured to provide a first electron beam, where the first MEMS is configured to convert the first electron beam into the plurality of first beamlets, and the second particle beam source is a second electron beam source configured to provide a second electron beam, where the third MEMS is configured to convert the second electron beam into the plurality of second beamlets. In an embodiment, the second MEMS is a first microchannel MEMS and is configured to provide a first precursor gas flow to each first target spot corresponding to the plurality of first beamlets in the first repair region of the target wafer, and the fourth MEMS is a second microchannel MEMS and is configured to provide a second precursor gas flow to each second target spot corresponding to the plurality of second beamlets in the second repair region of the target wafer. In an embodiment, the wafer repairing system further includes a first detecting beam generator configured to emit a first detecting beam to scan a top surface of the target wafer deposed in the first chamber, and a first detector configured to detect a first reflected beam of the first detecting beam from the surface of the target wafer and image the surface of the target wafer based on the first reflected beam of the first detecting beam. In an embodiment, the wafer repairing system further includes a second detecting beam generator configured to emit a second detecting beam to scan the top surface of the target wafer disposed in the second chamber, and a second detector configured to detect a second reflected beam of the second detecting beam from the surface of the target wafer and image the surface of the target wafer based on the second reflected beam of the second detecting beam.

According to some embodiments of the present disclosure, a method for repairing a target wafer is provided. The method includes emitting, by a particle beam source of the repairing apparatus, a plurality of beamlets to irradiate a repair region of a target wafer in a chamber of a repairing apparatus. The method further includes injecting, by a plurality of gas inlets of the repairing apparatus, a precursor gas to the repair region of the target wafer to repair defects in the repair region of the target wafer.

According to some embodiments of the present disclosure, a repairing system is provided. The repairing system includes a first repairing apparatus, a second repairing apparatus, and a transfer mechanism coupling and/or connecting the first repairing apparatus and the second repairing apparatus. Each of the first repairing apparatus and the second repairing apparatus includes a chamber configured to load a target wafer, and a particle beam source configured to emit at least one beamlets to irradiate a repair region of the target wafer. Each of the first repairing apparatus and the second repairing apparatus further includes at least one gas inlets configured to inject a precursor gas to the repair region of the target wafer to repair defects in the repair region of the target wafer.

The foregoing outlines features of several embodiments or examples so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments or examples introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A target wafer repairing apparatus, comprising:
a chamber;
a particle beam source configured to emit one or more beamlets to irradiate a repair region of a target wafer disposed in the chamber; and
at least one gas inlet configured to inject a precursor gas to the repair region of the target wafer to repair defects in the repair region of the target wafer.

2. The target wafer repairing apparatus according to claim 1, wherein:
the particle beam source includes at least one gun head configured to emit the one or more beamlets, and
each of the at least one gun head is movable to irradiate a corresponding beamlet of the one or more beamlets to a target spot in the repair region of the target wafer.

3. The target wafer repairing apparatus according to claim 2, wherein:
the particle beam source is an ion beam source configured to provide an ion beam, wherein the at least one gun head is configured to convert the ion beam into the one or more beamlets.

4. The target wafer repairing apparatus according to claim 2, wherein:
the particle beam source is an electron beam source configured to provide an electron beam, wherein the at least one gun head is configured to convert the electron beam into the one or more beamlets.

5. The target wafer repairing apparatus according to claim 1, wherein:
the at least one beamlet is configured to be directed normal to a top surface of the target wafer.

6. The target wafer repairing apparatus according to claim 1, wherein:
each of the at least one gas inlet is arranged to inject the precursor gas at a corresponding target spot in the repair region of the target wafer.

7. The target wafer repairing apparatus according to claim 1, wherein:
the emitting of the one or more beamlets and the injecting of the precursor gas are synchronized.

8. The target wafer repairing apparatus according to claim 1, further comprising:
a detecting beam generator configured to emit a detecting beam to scan a surface of the target wafer, and
a detector configured to detect a reflected beam of the detecting beam from the surface of the target wafer and image the surface of the target wafer based on the detected reflected beam.

9. The target wafer repairing apparatus according to claim 8, wherein:
the detecting beam generator is configured to emit the detecting beam in a tilted direction relative to a normal direction to a top surface of the target wafer.

10. A wafer repairing system comprising a first wafer repairing apparatus, wherein the first wafer repairing apparatus comprises:
a first chamber;
a first particle beam source configured to emit a first particle beam into the first chamber;
a first micro-electro-mechanical system (MEMS) configured to split the first particle beam into a plurality of first beamlets to irradiate a first repair region of a target wafer disposed in the first chamber; and
a second MEMS configured to inject a first precursor gas to the first repair region of the target wafer to repair first defects in the first repair region of the target wafer.

11. The wafer repairing system according to claim 10, further comprising:
at least one second wafer repairing apparatus; and
a transfer mechanism configured to transfer the target wafer between the first wafer repairing apparatus and the at least one second wafer repairing apparatus, wherein each of the at least one second wafer repairing apparatus comprises:
a second chamber;
a second particle beam source configured to emit a second particle beam into the second chamber;
a third MEMS configured to split the second particle beam into a plurality of second beamlets to irradiate a second repair region of the target wafer disposed in the second chamber; and
a fourth MEMS configured to inject a second precursor gas to the second repair region of the target wafer to repair second defects in the second repair region of the target wafer.

12. The wafer repairing system according to claim 11, wherein:
the first MEMS includes a plurality of first apertures arranged in a first array and configured to split the first particle beam into a plurality of first beamlets, and
each of the plurality of first apertures is configured to project a corresponding first beamlet of the plurality of first beamlets to a first target spot in the first repair region of the target wafer or block the corresponding first beamlet of the plurality of first beamlets from the first target spot in the first repair region of the target wafer.

13. The wafer repairing system according to claim 12, wherein:
the third MEMS includes a plurality of second apertures arranged in a second array and configured to split the second particle beam into a plurality of second beamlets, and
each of the plurality of second apertures is configured to project a corresponding second beamlet of the plurality of second beamlets to a second target spot in the second repair region of the target wafer or block the corresponding second beamlet of the plurality of second beamlets from the second target spot in the second repair region of the target wafer.

14. The wafer repairing system according to claim 13, wherein:
the first particle beam source is a first ion beam source configured to provide a first ion beam, wherein the first MEMS is configured to convert the first ion beam into the plurality of first beamlets, and
the second particle beam source is a second ion beam source configured to provide a second ion beam, wherein the third MEMS is configured to convert the second ion beam into the plurality of second beamlets.

15. The wafer repairing system according to claim 13, wherein:
the first particle beam source is a first electron beam source configured to provide a first electron beam, wherein the first MEMS is configured to convert the first electron beam into the plurality of first beamlets, and
the second particle beam source is a second electron beam source configured to provide a second electron beam, wherein the third MEMS is configured to convert the second electron beam into the plurality of second beamlets.

16. The wafer repairing system according to claim 11, wherein:
the second MEMS is a first microchannel MEMS and is configured to provide a first precursor gas flow to each first target spot corresponding to the plurality of first beamlets in the first repair region of the target wafer, and
the fourth MEMS is a second microchannel MEMS and is configured to provide a second precursor gas flow to each second target spot corresponding to the plurality of second beamlets in the second repair region of the target wafer.

17. The wafer repairing system according to claim 11, further comprising:
a first detecting beam generator configured to emit a first detecting beam to scan a top surface of the target wafer deposed in the first chamber,
a first detector configured to detect a first reflected beam of the first detecting beam from the surface of the target wafer and image the surface of the target wafer based on the first reflected beam of the first detecting beam,
a second detecting beam generator configured to emit a second detecting beam to scan the top surface of the target wafer disposed in the second chamber, and
a second detector configured to detect a second reflected beam of the second detecting beam from the surface of the target wafer and image the surface of the target wafer based on the second reflected beam of the second detecting beam.

18. A method for repairing a target wafer, comprising:
emitting, by a particle beam source of a repairing apparatus, at least one beamlet to irradiate a repair region of a target wafer in a chamber of the repairing apparatus; and
injecting, by at least one gas inlet of the repairing apparatus, a precursor gas to the repair region of the target wafer to repair defects in the repair region of the target wafer.

19. The method of claim 18, wherein:
the particle beam source includes at least one gun head configured to emit the at least one beamlet, and
each of the at least one gun head is movable to irradiate a corresponding beamlet of the at least one beamlet to a target spot in the repair region of the target wafer.

20. The method of claim 18, further comprising:
emitting, by a detecting beam generator of the repairing apparatus, a detecting beam to scan a top surface of the target wafer;
detecting a reflected beam of the detecting beam from the top surface of the target wafer to image the top surface of the target wafer based on the detected reflected beam; and determining whether the target wafer is repaired based on the imaging of the top surface of the target wafer.
